(19) United States
(12) Patent Application Publication
(10) Pub. No.: US 2014/0159255 A1
(43) Pub. Date: Jun. 12, 2014

(54) CONTACT PAD STRUCTURE

(71) Applicants: Chung-Hsien Li, Taichung City (TW); Kuo-Hsing Chen, New Taipei City (TW); Chia-Ching Lu, Taichung City (TW); Yu-Ting Chen, Taoyuan County (TW)

(72) Inventors: Chung-Hsien Li, Taichung City (TW); Kuo-Hsing Chen, New Taipei City (TW); Chia-Ching Lu, Taichung City (TW); Yu-Ting Chen, Taoyuan County (TW)

(73) Assignee: WINTEK CORPORATION, Taichung City (TW)

(21) Appl. No.: 14/098,495

(22) Filed: Dec. 5, 2013

(30) Foreign Application Priority Data
Dec. 6, 2012 (TW) 101145836

(51) Int. Cl. H01L 23/60; H01L 23/00

(52) U.S. Cl. CPC H01L 23/60; H01L 24/05
USPC 257/782

(57) ABSTRACT

A contact pad structure disposed on a peripheral region of a substrate is provided. The contact pad structure includes a transparent conductive pattern, a metal conductive pattern, and a protection layer. The transparent conductive pattern has a bonding region, a first side region, a second side region, a third side region and a fourth side region. The first, the second, the third, and the fourth side regions sequentially surround the bonding region. The metal conductive pattern without overlapping the bonding region has a first contact region, a second contact region and a first connection region. The first contact region contacts the first side region. The second contact region contact the third side region. The first connection region is connected between the first contact region and the second contact region. The protection layer covering the metal conductive pattern has a protection layer opening exposing the bonding region.

### CROSS-REFERENCE TO RELATED APPLICATION

This application claims the priority benefit of Taiwan application serial no. 101145836, filed on Dec. 6, 2012. The entirety of the above-mentioned patent application is hereby incorporated by reference herein and made a part of this specification.

### BACKGROUND OF THE INVENTION

1. Field of the Invention

The present invention relates to a contact pad structure, and more particularly to a contact pad structure made of multiple materials.

2. Description of Related Art

Among kinds of electronic devices, a driving chip is required to input and/or transmit a corresponding command signal for accessing various functions such as displaying an image, sensing a touch, making a sound, etc. Therefore, the electronic devices need be bonded with the driving chips. Regarding a touch sensing panel, touch sensing element thereon such as the sensing electrodes are electrically connected to the driving chip through contact pads formed in the substrate thereof. Accordingly, the contact pad structure has an influence on the quality of the touch sensing panel.

Generally, a metal has better electrically conductive property than an oxide conductive material. Accordingly, the contact pad structure made of metal can have desirable signal transmission property. However, the metal is easily oxidized, which causes unfavorable reliability of the contact pad structure. Therefore, a contact pad structure made of multiple materials is provided, in which the oxide conductive material is used for connecting the metal wire and the contact pad structure is bonded to the driving chip through the oxide conductive material. Such design is conducive to preventing from the poor reliability caused by the oxidation of the metal which is exposed.

Nevertheless, the significant contact resistance between the metal and the oxide conductive material becomes another problem to be resolved. Particularly, in the case that the contact pad structure made of the multiple materials is used for the electrostatic discharge (ESD) protection purpose, the instantaneous current usually fails to be transmitted out and thus accumulates at the interface between the metal and the oxide conductive material, which damages and even breaks the contact pad structure.

### SUMMARY OF THE INVENTION

The present invention is directed to a contact pad structure having desirable reliability.

The invention provides a contact pad structure disposed on a peripheral region of a substrate. The contact pad structure includes a transparent conductive pattern, a metal conductive pattern, and a protection layer. The transparent conductive pattern is disposed on the substrate and has a bonding region, a first side region, a second side region, a third side region and a fourth side region. The first side region, the second side region, the third side region and the fourth side region together surround the bonding region. The first side region is opposite to the third side region and the second side region is opposite to the fourth side region. The metal conductive pattern is disposed on the transparent conductive pattern and is not overlapped with the bonding region. The metal conductive pattern has a first contact region, a second contact region and a first connection region. The first contact region contacts the first side region. The second contact region contact the third side region. The first connection region is connected between the first contact region and the second contact region. The protection layer covers the metal conductive pattern and has a protection layer opening. The protection layer opening exposes the bonding region of the transparent conductive pattern.

According to an embodiment of the present invention, the first connection region is in contact with the second side region.

According to an embodiment of the present invention, the first connection region is separated from the transparent conductive pattern by a distance.

According to an embodiment of the present invention, the metal conductive pattern further has a second connection region. The second connection region is connected between the first contact region and the second contact region. The second connection region and the first connection region are located at two opposite sides of the bonding region. The first connection region is in contact with the second side region. The second connection region is optionally in contact with the fourth side region. Alternately, the first connection region is separated from the transparent conductive pattern by a distance. The second connection region is optionally separated from the transparent conductive pattern by a distance. A width of the protection layer opening in the protection layer is smaller than a distance between the first connection region and the second connection region of the metal conductive pattern.

According to an embodiment of the present invention, a width of the protection layer opening in the protection layer is smaller than a distance between the first contact region and the second contact region of the metal conductive pattern such that the metal conductive pattern is completely covered.

According to an embodiment of the present invention, an active region of the substrate is disposed with a functional element. The peripheral region surrounds the active region and the metal conductive pattern is electrically connected to the functional element. Herein, the functional element includes a touch sensing element, a display element or a switching element.

According to an embodiment of the present invention, the peripheral region of the substrate is further disposed with a first decoration layer located between the substrate and the transparent conductive pattern. In addition, the peripheral region of the substrate can further be disposed with a second decoration layer. The transparent conductive layer and the metal conductive layer are located between the second decoration layer and the first decoration layer, and the second decoration layer has a decoration layer opening exposing the bonding region of the transparent conductive pattern.

In view of the above, the contact pad structure according to the embodiments of the invention is formed by a transparent conductive pattern and a metal conductive pattern, wherein the metal conductive pattern is not overlapped with the bonding region of the transparent conductive pattern and is completely covered by the protection layer. Accordingly, the metal conductive pattern is not exposed, which prevents from the poor reliability of the contact pad structure caused by the oxidation of the metal conductive pattern. Furthermore, the transparent conductive pattern and the metal conductive pattern are in contact with each other at multiple regions, which conduces to avoiding the current crowd effect at the interface between the transparent conductive pattern and the metal conductive pattern. As a result, the contact pad structure according to the embodiments of the present invention has desirable transmission quality.

In order to make the aforementioned and other features and advantages of the invention more comprehensible, embodiments accompanying figures are described in detail below.

### BRIEF DESCRIPTION OF THE DRAWINGS

FIG. 1A is a schematic top view showing a contact pad structure according to a first embodiment of the present invention.

FIG. 1B is a schematic exploded view showing each part of the contact pad structure depicted in FIG. 1A.

FIG. 1C is a schematic cross-sectional view showing the contact pad structure taken along the line I-I′ of FIG. 1A.

FIG. 1D is a schematic cross-sectional view showing the contact pad structure taken along the line II-II′ of FIG. 1A.

FIG. 2A is a schematic top view showing a contact pad structure according to a second embodiment of the present invention.

FIG. 2B is a schematic cross-sectional view showing the contact pad structure taken along the line of FIG. 2A.

FIG. 3A is a schematic top view showing a contact pad structure according to a third embodiment of the present invention.

FIG. 3B is a schematic cross-sectional view showing the contact pad structure taken along the line IV-IV′ of FIG. 3A.

FIG. 4A is a schematic top view showing a contact pad structure according to a fourth embodiment of the present invention.

FIG. 4B is a schematic cross-sectional view showing the contact pad structure taken along the line V-V′ of FIG. 4A.

FIG. 5A is a schematic view showing a touch sensing panel according to an embodiment of the present invention.

FIG. 5B is a schematic cross-sectional view showing the touch sensing panel taken along the line VI-VI′ of FIG. 5A.

FIG. 6 is a cross-sectional view showing a touch sensing panel according to another embodiment of the present invention.

### DESCRIPTION OF EMBODIMENTS

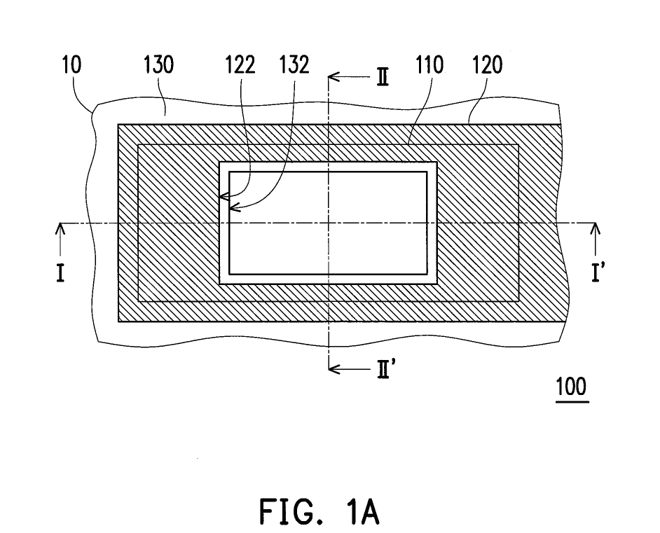

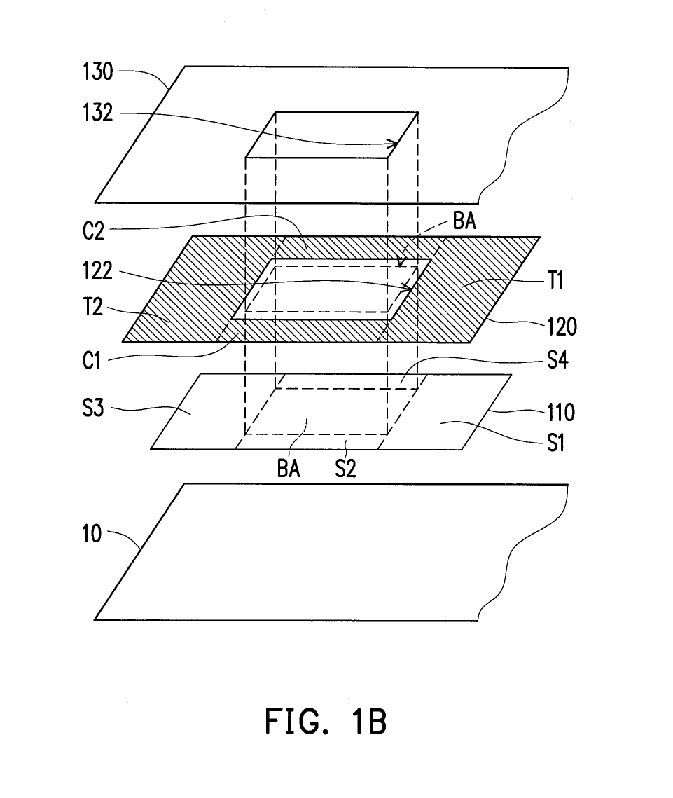

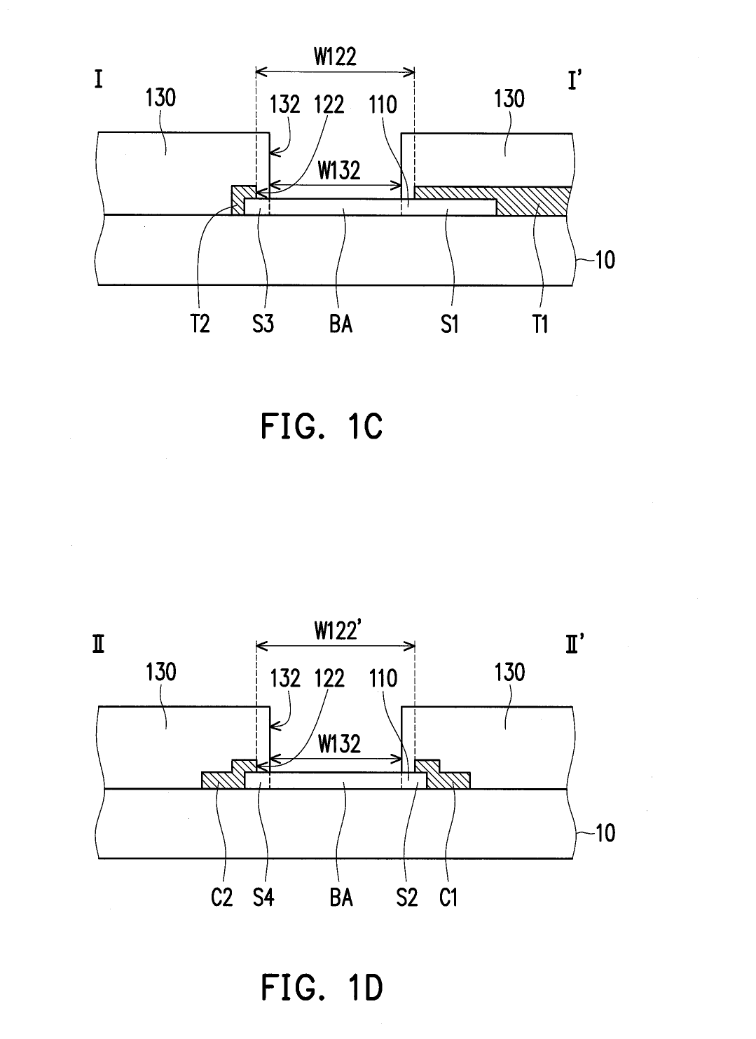

FIG. 1A is a schematic top view showing a contact pad structure according to a first embodiment of the present invention and FIG. 1B is a schematic exploded view showing each part of the contact pad structure depicted in FIG. 1A. Referring to both FIGS. 1A and 1B, the contact pad structure 100 is disposed on a substrate 10 and the contact pad structure 100 includes a transparent conductive pattern 110, a metal conductive pattern 120 and a protection layer 130 which are sequentially stacked on the substrate 10. In the embodiment, the protection layer 130 can be made of insulation material such as organic material, inorganic material (SiO2 or SiNx) and so on. Accordingly, the transparent conductive layer 110 is located between the metal conductive pattern 120 and the substrate 10 and the transparent conductive pattern 110 and the metal conductive pattern 120 are both located between the protection layer 130 and the substrate 10.

The transparent conductive pattern 110 of the present embodiment has a bonding region BA, a first side region S1, a second side region S2, a third side region S3 and a fourth side region S4. The first side region S1, the second side region S2, the third side region S3 and the fourth side region S1 together surround the bonding region BA, wherein the bonding region BA is used for bonding with a driving chip through a conductive material such as a conductive adhesive. In the case that the transparent conductive pattern 110 has a rectangle pattern, the first side region S1, the second side region S2, the third side region S3 and the fourth side region S4 respectively corresponds to the four sides of the rectangle pattern, for example. Nevertheless, in the case that the transparent conductive pattern 110 does not have a rectangle pattern, the periphery of the bonding region BA can be divided into four portions which are respectively defined as the first side region S1, the second side region S2, the third side region S3 and the fourth side region S4.

In addition, in the present embodiment, the first side region S1 is opposite to the third side region S3 and the second side region S2 is opposite to the fourth side region S4. If the contact pad structure 100 is viewed from the terminal thereof along its extending direction, as shown in FIG. 1B, the first side region S1 and the third side region S3 are respectively located at the front and the back of the bonding region BA while the second side region S2 and the fourth side region S4 are respectively located at the right and the left of the bonding region BA.

The metal conductive pattern 120 has a first contact region T1, a second contact region T2, a first connection region C1 and a second connection region C2. The first contact region T1 and the second contact region T2 are respectively located at two opposite sides of the bonding region BA of the transparent conductive pattern 110.

The first connection region C1 and the second connection region C2 are also respectively located at another two opposite sides of the bonding region BA of the transparent conductive pattern 110. The first connection region C1 and the second connection region C2 are individually connected between the first contact region T1 and the second contact region T2. In specific, the first contact region T1, the first connection region C1, the second contact region T2, and the second connection region C2 are sequentially connected to form a metal pattern opening 122 which corresponds to bonding region BA of the transparent conductive pattern 110. The protection layer 130 has a protection layer opening 132 corresponding to the bonding region BA of the transparent conductive pattern 110. In specific, the region of the transparent conductive pattern 110 exposed by the protection layer opening 132 is served as the bonding region BA.

FIG. 1C is a schematic cross-sectional view showing the contact pad structure taken along the line I-I′ of FIG. 1A and FIG. 1D is a schematic cross-sectional view showing the contact pad structure taken along the line II-II′ of FIG. 1A. Referring to FIG. 1A, FIG. 1C and FIG. 1D, the first contact region T1, the first connection region C1, the second contact region T2 and the second connection region C2 are exemplarily in contact with the first side region S1, the second side region S2, the third side region S3 and the fourth side region S4 of the transparent conductive pattern 110, respectively, such that the metal conductive pattern 120 is electrically connected to the transparent conductive pattern 110. As shown in FIG. 1C, the size W122 of the metal pattern opening 122 is equivalent to the distance between the first contact region T1 and the second contact region T2. As shown in FIG. 1D, the size W122′ of the metal pattern opening 122 is equivalent to the distance between the first connection region C1 and the second connection region C2. According to the cross sectional views shown in FIG. 1C or FIG. 1D, the size W132 of the protection layer opening 132 is smaller than the size W122 or W122′ of the metal pattern opening 122 so that the metal conductive pattern 120 is not overlapped with the bonding region BA. Therefore, the protection layer 130 substantially covers the whole of the metal conductive pattern 120. The metal conductive pattern 120 is not exposed, which prevents the metal conductive pattern 120 from the increase in the resistance caused by the oxidation effect.

Furthermore, the transparent conductive pattern 110 and the metal conductive pattern 120 have different conductivities, and thus the contact resistance between the two would likely have influence on the quality of the contact pad structure 100. However, the transparent conductive pattern 110 and the metal conductive pattern 120 are at least in contact with each other at four regions, which increases the paths that a current flow from the metal conductive pattern 120 to the transparent conductive pattern 110. Particularly, owing to the increase of the current paths, a large current flowing from the metal conductive pattern 120 to the transparent conductive pattern 110 is prevented from crowding at a specific region, wherein the crowding of the large current damages the contact pad structure 100. Accordingly, the contact pad structure 100 can have desirable transmission quality and reliability, which facilitates to applying the contact pad structure 100 in the ESD protection circuit in addition to the application in the circuit for transmitting common electronic signals. Namely, the contact pad structure 100 can be served as a part of the ESD protection ring in an electronic device.

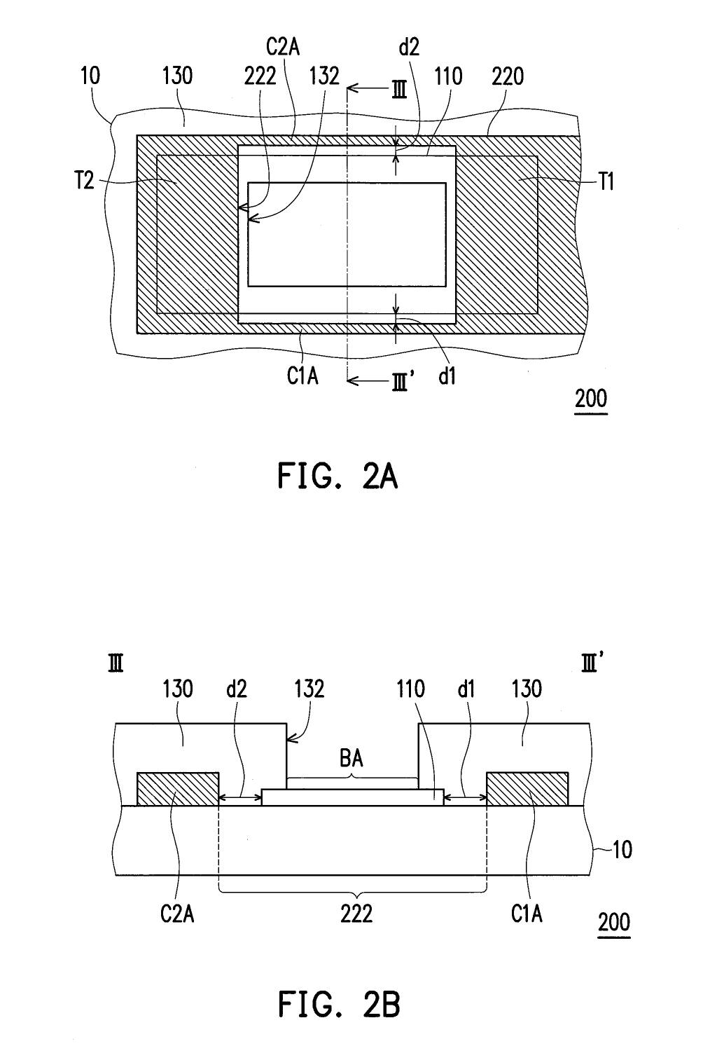

It should be noted that although the embodiment uses the first connection region C1 and the second connection region C2 of the metal conductive pattern 120 in contact with the transparent conductive pattern 110 as an example, the present invention is not limited thereto. FIG. 2A is a schematic top view showing a contact pad structure according to a second embodiment of the present invention and FIG. 2B is a schematic cross-sectional view showing the contact pad structure taken along the line III-III′ of FIG. 2A. Referring to both FIGS. 2A and 2B, the contact pad structure 200 is disposed on a substrate 10 and the contact pad structure 200 includes a transparent conductive pattern 110, a metal conductive pattern 220 and a protection layer 130, in which the structural designs of the substrate 10, the transparent conductive pattern 110 and the protection layer 130 can be referred to the above embodiment and are not reiterated hereinafter. In the present embodiment, the metal conductive pattern 220 has a first contact region T1, a second contact region T2, a first connection region C1A and a second connection region C2A. The first contact region T1, the second contact region T2, the first connection region C1A and the second connection region C2A surround the bonding region BA and define the metal pattern opening 222.

The first contact region T1 and the second contact region T2 are both overlapped with and in contact with the transparent conductive pattern 110. Nevertheless, the first connection region C1A and the second connection region C2A are respectively separated from the transparent conductive pattern 110 by a distance d1 and a distance d2. Therefore, the first connection region C1A and the second connection region C2A are neither in contact with the transparent conductive pattern 110. Based on the design of the present embodiment, the current can flow from the metal conductive pattern 110 to the transparent conductive pattern 220 at two regions, the first contact region T1 and the second contact region T2. Accordingly, the current crowding effect at the interface between the transparent conductive pattern 110 and the second conductive pattern 220 can be diminished.

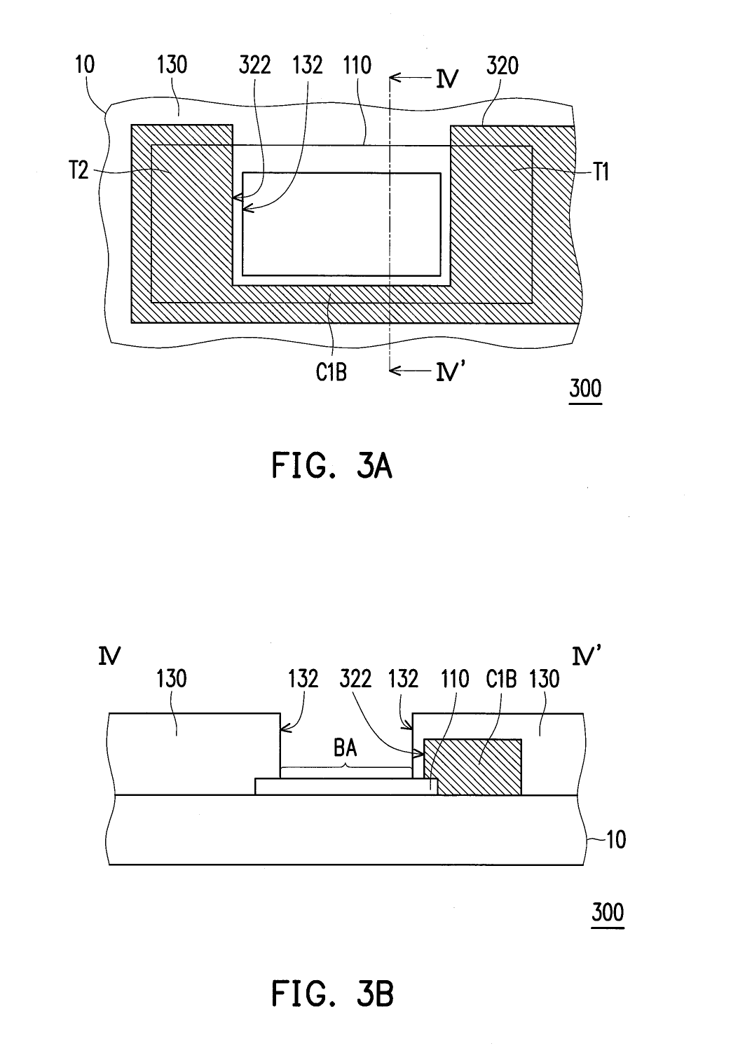

It should be noted that although the embodiment depicted in FIG. 1A through FIG. 1D uses the metal conductive pattern 120 completely surrounding the bonding region BA and having the closed metal pattern opening 122 as an example, the present invention is not limited thereto. FIG. 3A is a schematic top view showing a contact pad structure according to a third embodiment of the present invention and FIG. 3B is a schematic cross-sectional view showing the contact pad structure taken along the line IV-IV′ of FIG. 3A. Referring to both FIGS. 3A and 3B, the contact pad structure 300 is disposed on a substrate 10 and the contact pad structure 300 includes a transparent conductive pattern 110, a metal conductive pattern 320 and a protection layer 130, in which the structural designs of the substrate 10, the transparent conductive pattern 110 and the protection layer 130 can be referred to the above embodiment and are not reiterated hereinafter. In the present embodiment, the metal conductive pattern 320 has a first contact region T1, a second contact region T2 and a first connection region C1B. The first contact region T1, the second contact region T2 and the first connection region C1B surround the bonding region BA and are in contact with the transparent conductive pattern 110.

The first contact region T1, the second contact region T2 and the first connection region C1B define a metal pattern opening 322 which is not closed-shaped. Therefore, the first contact region T1 and the second contact region T1 are connected to two terminals of the first connection region C1B, which forms a U-like pattern. Based on the design of the present embodiment, the current can flow from the metal conductive pattern 110 to the transparent conductive pattern 320 at three regions, the first contact region T1, the second contact region T2 and the first connection region C1B. Accordingly, the current crowding effect at the interface between the transparent conductive pattern 110 and the second conductive pattern 320 can be diminished.

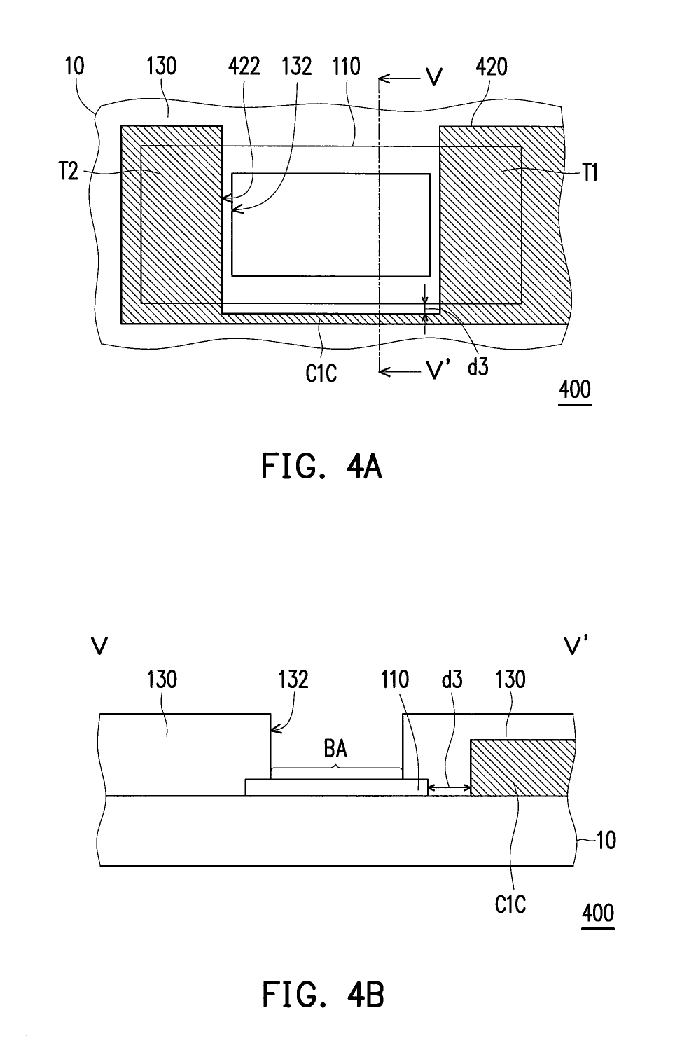

FIG. 4A is a schematic top view showing a contact pad structure according to a fourth embodiment of the present invention and FIG. 4B is a schematic cross-sectional view showing the contact pad structure taken along the line V-V′ of FIG. 4A. Referring to both FIGS. 4A and 4B, the contact pad structure 400, similar to the contact pad structure 300, is disposed on a substrate 10 and the contact pad structure 400 includes a transparent conductive pattern 110, a metal conductive pattern 420 and a protection layer 130, in which the structural designs of the substrate 10, the transparent conductive pattern 110 and the protection layer 130 can be referred to the first and the third embodiments and are not reiterated hereinafter. In the present embodiment, the metal conductive pattern 420 has a first contact region T1, a second contact region T2 and a first connection region C1C. The first contact region T1, the second contact region T2 and the first connection region C1C surround the bonding region BA and the first contact region T1 and the second contact region T2 are in contact with the transparent conductive pattern 110. It is noted that the difference of the present embodiment from the third embodiment lies in that the first connection region C1C is separated from the transparent conductive pattern 110 by a distance d3 and is not in contact with the transparent conductive pattern 110.

Any of the contact pad structures 100-400 in the above embodiments can be fabricated on a display panel, a touch sensing panel, or other electronic device for bonding with the driving chip. A touch sensing panel is illustrated below as an example. Nevertheless, the present invention should not be construed as limited to the embodiments set forth herein.

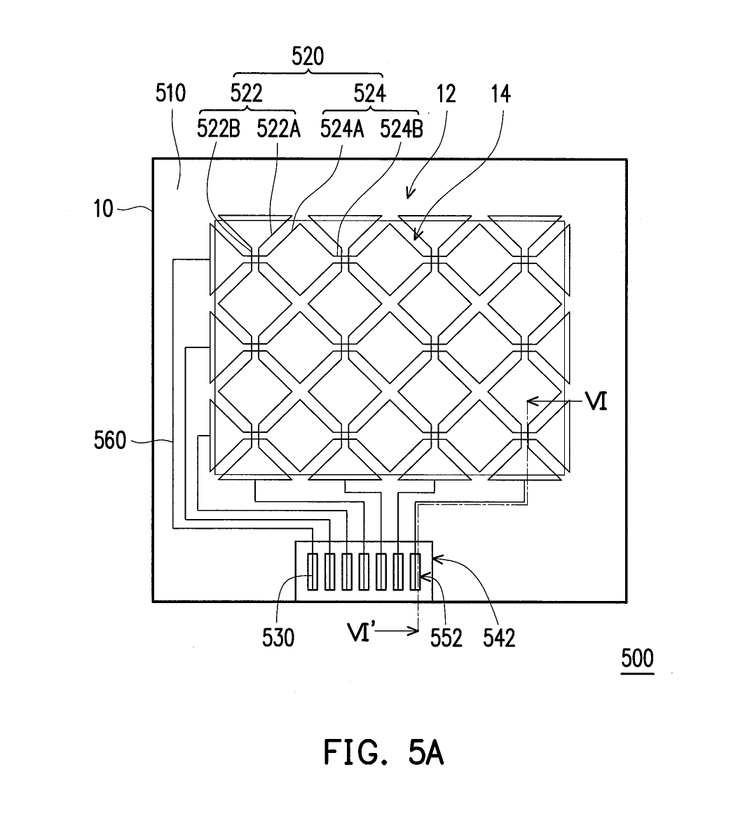

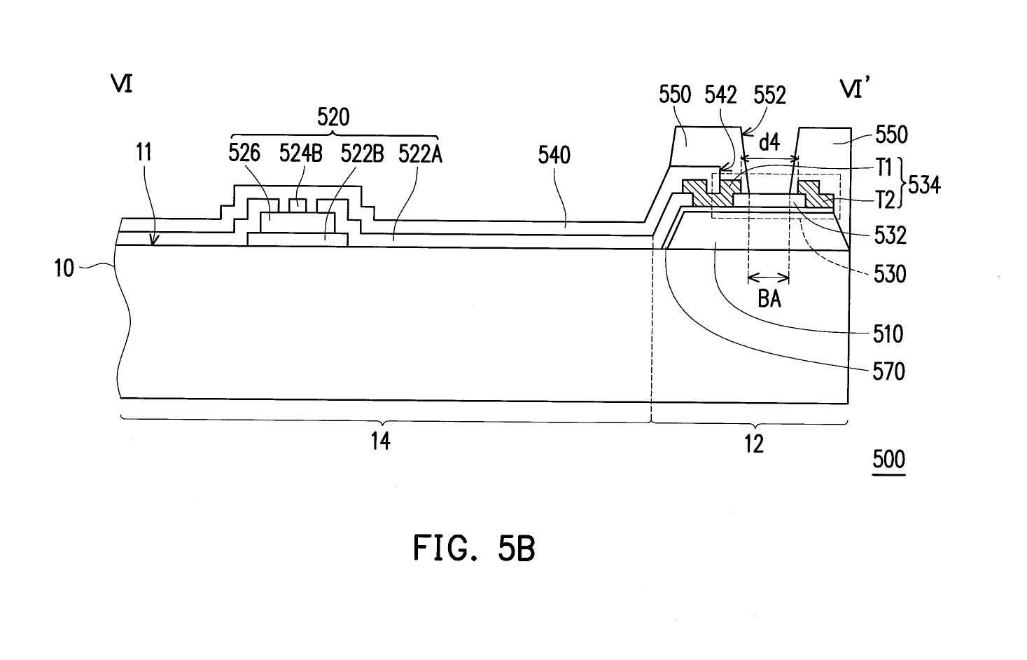

FIG. 5A is a schematic view showing a touch sensing panel according to an embodiment of the present invention and FIG. 5B is a schematic cross-sectional view showing the touch sensing panel taken along the line VI-VI′ of FIG. 5A. Referring to FIG. 5A and FIG. 5B, a touch sensing panel 500 includes a substrate 10, a decoration layer 510, a touch sensing element 520, a plurality of contact pad structures 530, a first protection layer 540, a second protection layer 550 and a plurality of conductive wires 560. The substrate 10 has a peripheral region 12 and an active region 14. The decoration 510 is configured at the peripheral region 12 for proving a decoration effect. The touch sensing element 520 is a functional element for proving the touch sensing function and is configured in the active region 14. The contact pad structures 530 are configured at the peripheral region 12 and are electrically connected to the touch sensing element 520 through the corresponding conductive wires 560. Furthermore, the first protection layer 540 covers the touch sensing element 520 and the second protection layer 550 covers the peripheral region 12. In an example, the decoration layer 510 and the second protection layer 550 can optionally cover on the edge (sidewall) of the substrate 10 owing to the fabrication process.

The touch sensing panel 500 of the present embodiment is an exemplary example for illustrating the scope of the invention so that the functional element located in the active region 14 being the touch sensing element 520 is taken as an example. Nevertheless, in other embodiments, the functional element configured in the active region 14 can be a display element, a switching element, a photo sensor, or other element capable of providing particular function.

In specific, the decoration layer 510 is disposed at the peripheral region 14 for shielding the conductive wires 560 and the contact pad structures 530, so that a user would not see the parts. Therefore, the decoration layer 510 can be formed by an ink or a photoresist pattern. In one embodiment, the decoration layer 510 can be a structure formed by a black ink pattern, a white ink pattern or a stack of multiple ink patterns.

The touch sensing element 520 can be consisted of a plurality of first sensing series 522 and a plurality of second sensing series 524. The first sensing series 522 each is formed by a plurality of sensing electrodes 522A serially connected through a plurality of bridge electrode 522B and the second sensing series 524 each is formed by a plurality of sensing electrodes 524A serially connected through a plurality of bridge electrodes 524B. The first sensing series 522 and the second sensing series 524 are interlaced with each other. Furthermore, the touch sensing element 520 can further include insulation patterns 526 configured where the first sensing series 522 and the second sensing series 524 are overlapped.

For having sufficient light transparency, the sensing electrodes 522A and the sensing electrodes 524A can be formed by a transparent conductive material (such as ITO). In the present embodiment, a buffer layer 570 can be further disposed on the surface of the decoration layer 510, and the buffer layer 570 can be located between the decoration layer 510 and the sensing electrodes 522A or between the decoration layer and the sensing electrodes 524A. A material of the buffer layer 570 is, for example, SiO₂ for improving the attachment between the transparent conductive material and the decoration layer 510. In another one embodiment, another buffer layer (not shown) can be optionally disposed on a surface 11 of the substrate 10 and the buffer layer can be a silicon dioxide layer for improving the attachment between the substrate 10 and the decoration 510 and the attachment between the substrate 10 and the touch sensing element 520. Nevertheless, the present invention should not be construed as limited to the embodiments set forth herein. According to other embodiments, the sensing electrodes 522A and the sensing electrodes 524A can be directly formed on the decoration layer 510. In addition, the touch sensing element 520 being sensing series is taken as an example, and the touch sensing element 520 in other embodiments can be a plurality of electrode patterns arranged in an array, a plurality of electrode bars, a plurality of photo sensors, or other elements capable of sensing a touch activity.

In the present embodiment, the specific design of at least one of the contact pad structures 530 can be selected from at least one of the contact pad structures 100˜400 depicted in the above. Therefore, the contact pad structure 530, for example, can include the transparent conductive pattern 532 and the metal conductive pattern 534, wherein the transparent conductive pattern 532 has the structural designs of the transparent conductive pattern 110 mentioned in the above and the metal conductive pattern 534 can have any of the designs of the metal conductive patterns 120, 220, 320 and 420 depicted in above. In addition, the second protection layer 550 covering on the contact pad structure 530 can be served as the protection layer 130 depicted in the above embodiments. In addition, the second protection layer 550 can be made of insulation material such as organic material, inorganic material (SiO2 or SiNx) and so on.

Specifically, the second protection layer 550 has a protection layer opening 552 exposing the bonding region BA of the transparent conductive pattern 532. Furthermore, the metal conductive pattern 534 has the first contact region T1 and the second contact region T2 directly in contact with the transparent conductive pattern 532, for example. The distance d4 between the first contact region T1 and the second contact region T2 is greater than the size of the protection layer opening 522. Therefore, the second protection layer 550 substantially covers the whole of the metal conductive pattern 534, which prevents the metal conductive pattern 534 from being oxidized due to be exposed. Thereby, the reliability of the contact pad structure 530 can be improved.

The specific design of at least one of the contact pad structures 530 can be selected from at least one of the contact pad structures 100˜400 depicted in the above. Therefore, similar to the above embodiment, the contact pad structure 530 can have desirable signal transmission quality and conduce to improve the characteristic of the touch sending panel 500. In the present embodiment, each of the first sensing series 522 and the second sensing series 524 can be connected to one corresponding contact pad structure 530 through one conductive wire 560. However, the contact pad structures 530 are not restricted to be connected with the touch sensing element 520. For example, at least one of the contact pad structures 530 can be connected to an ESD protection ring of the touch sensing panel 500 or can be a dummy contact pad.

The bonding region BA of the contact pad structure 520 in the present embodiment is required to be exposed for bonding with the driving chip. Therefore, the first protection layer 540 covering most area of the substrate 10 can have a padding region opening 542 for exposing the contact pad structures 530. In addition, the first protection layer 540 can have a single-layer structure or a multi-layers structure and the material thereof includes silicon dioxide, silicon nitride, silicon oxynitride, or a combination thereof.

In FIG. 5A, the number of the padding region opening 542 is one which exposes all the contact pad structures 530 and the number of the protection layer opening 522 is a plural each of which exposes one corresponding contact pad structure 530. Nevertheless, the present invention should not be construed as limited to the embodiments set forth herein. In other embodiment, the number of the padding region opening 542 can be a plural so that each padding region opening 542 corresponds to one protection layer opening 522. Alternately, the number of the protection layer opening 522 can be one. The protection layer opening 522 corresponds to the single padding region opening 542 and exposes all the contact pad structures 530.

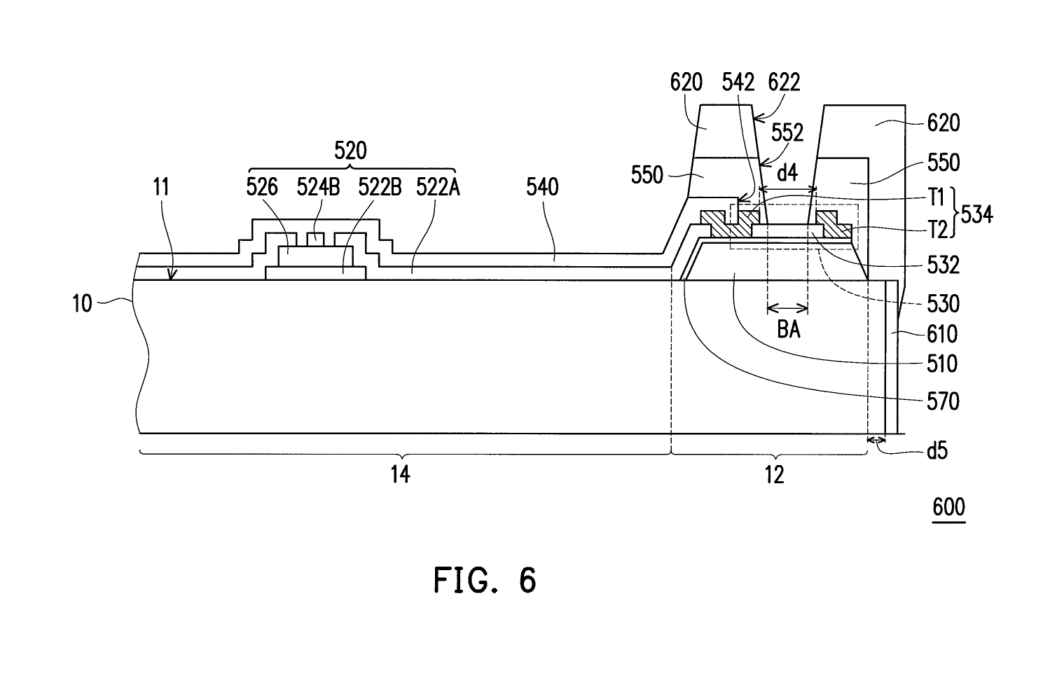

In the above embodiment of the touch panel 500, the edges of the decoration layer 510 and the substrate 10 are aligned, but the invention is not limited thereto. For example, FIG. 6 is a cross-sectional view showing a touch sensing panel according to another embodiment of the present invention. Referring to FIG. 6, a touch sensing panel 600 is similar to the touch sensing panel 500, and the same elements are represented by the same reference numbers. Therefore, no further descriptions are provided herein. In the present embodiment, the touch sensing panel 600 includes the substrate 10, the decoration layer 510, the touch sensing element 520, the contact pad structures 530, the first protection layer 530, the first protection layer 540, the second protection layer 550 and the conductive wire 560 and further includes an reinforced layer 610 and another decoration layer 620. The reinforced layer 610 covers the sidewall of the substrate 10. The decoration layer 620 covers above the contact pad structures 530 and has a decoration layer opening 622 exposing the bonding region BA.

In the present embodiment, the decoration layer 510, different from that depicted in FIG. 5B, is not filled the whole of the peripheral region 12, and thus the decoration layer 510 is separated from the edge of the substrate 10 by a distance d5. For shielding the light leakage at the area between the decoration layer 510 and the edge of the substrate 10, the decoration layer 620 of the touch sensing panel 600 at least is filled in the whole area between the decoration layer 510 and the edge of the substrate 10. Herein, the decoration layer 510 can be named as a first decoration and the decoration layer 610 can be named as a second decoration layer. In other words, the touch display panel 600 features two decoration layers 510 and 610.

In the present embodiment, the method of fabricating the touch sensing panel 600 is as follows. First, a the decoration layer 510 is formed on a mother board (not shown). Next, the touch sensing element 520 and the contact pad structures 530 are fabricated on the mother board. Then, the first protection layer 540 and the second protection layer 550 are formed on the mother board to cover the touch sensing element 520 and the contact pad structures 530. After performing the above process, the mother board can be cut into the substrate 10 having the desirable shape via a cutting step, a grinding step, or the like. During the steps of cutting, grinding or the like, the sidewall of the substrate 10 may have cracks or mechanically weak regions. Therefore, in the present embodiment, the reinforced layer 610 can be formed on the sidewall of the substrate 10 for improving the mechanical property of the substrate 10. The cutting step for forming the substrate 10 is performed after the formation of the decoration layer 510 so that the edge of the decoration layer 510 may not be aligned to the edge of the substrate 10. Therefore, the another decoration layer 620 is subsequently formed on the substrate 10 for filling the region between the edge of the decoration layer 510 and the edge of the substrate 10.

In view of the above, the contact pad structure according to the invention is formed by stacking two materials, wherein the metal conductive pattern is in contact with a portion of the transparent conductive pattern and exposes the bonding region of the transparent conductive pattern. Therefore, the protection layer exposing the bonding region of the transparent conductive pattern can cover the whole of the metal conductive pattern, which prevents the contact pad structure from poor quality owing to the oxidation of the metal conductive pattern. Furthermore, the transparent conductive pattern and the metal conductive pattern are in contact with each other at multiple regions, which conduces to increasing the paths of the current flowing from the metal conductive pattern to the transparent conductive pattern and improving the conductive property of the contact pad structure. Particularly, the contact pad structure according to the embodiment of the invention is suitable for being applied in an ESD protection element for draining the electrostatic discharge current.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A contact pad structure disposed on a peripheral region of a substrate and comprising:
a transparent conductive pattern disposed on the substrate and having a bonding region, a first side region, a second side region, a third region and a fourth side region, wherein the first side region, the second side region, the third side region and the fourth side region surround the bonding region, the first side region is opposite to the third side region, and the second side region is opposite to the fourth side region;
a metal conductive pattern disposed on the transparent conductive pattern, not overlapped with the bonding region, and having a first contact region, a second contact region and a first connection region, wherein the first contact region is in contact with the first side region of the transparent conductive pattern, the second contact region is in contact with the third side region of the transparent conductive pattern, and the first connection region is connected between the first contact region and the second contact region; and
a protection layer covering the metal conductive pattern and having a protection layer opening exposing the bonding region of the transparent conductive pattern.

2. The contact pad structure as claimed in claim 1, wherein the first connection region is in contact with the second side region.

3. The contact pad structure as claimed in claim 1, wherein the first connection region is separated from the transparent conductive pattern by a distance.

4. The contact pad structure as claimed in claim 1, wherein the metal conductive pattern further has a second connection region connected between the first contact region and the second contact region, and the second connection region and the first connection region are located at two opposite sides of the bonding region respectively.

5. The contact pad structure as claimed in claim 4, wherein the first connection region is in contact with the second side region.

6. The contact pad structure as claimed in claim 4, wherein the second connection region is in contact with the fourth side region.

7. The contact pad structure as claimed in claim 4, wherein the first connection region is separated from the transparent conductive pattern by a distance.

8. The contact pad structure as claimed in claim 4, wherein the second connection region is separated from the transparent conductive pattern by a distance.

9. The contact pad structure as claimed in claim 4, wherein a width of the protection layer opening in the protection layer is smaller than a distance between the first connection region and the second connection region of the metal conductive pattern.

10. The contact pad structure as claimed in claim 9, wherein a width of the protection layer opening in the protection layer is smaller than a distance between the first contact region and the second contact region of the metal conductive pattern so that the metal conductive pattern is completely covered.

11. The contact pad structure as claimed in claim 1, wherein a width of the protection layer opening in the protection layer is smaller than a distance between the first contact region and the second contact region of the metal conductive pattern so that the metal conductive pattern is completely covered.

12. The contact pad structure as claimed in claim 1, wherein an active region of the substrate is disposed with a functional element, the peripheral region surrounds the active region, and the metal conductive pattern is electrically connected to the functional element.

13. The contact pad structure as claimed in claim 12, wherein the functional element includes a touch sensing element, a display element or a switching element.

14. The contact pad structure as claimed in claim 1, wherein the peripheral region of the substrate is further disposed with a first decoration layer located between the substrate and the transparent conductive pattern.

15. The contact pad structure as claimed in claim 14, wherein the peripheral region of the substrate is further disposed with a second decoration layer, the transparent conductive pattern and the metal conductive pattern are located between the second decoration layer and the first decoration layer, and the second decoration layer has a decoration layer opening exposing the bonding region of the transparent conductive pattern.
